(19) United States
(12) Patent Application Publication
(10) Pub. No.: US 2026/0129823 A1
(43) Pub. Date: May 7, 2026

(54) SEMICONDUCTOR STRUCTURE AND FORMING METHOD THEREFOR

(71) Applicant: CXMT Corporation, Hefei City (CN)

(72) Inventors: Kanyu CAO, Hefei City (CN); Wangrong GAO, Hefei City (CN); Lingxiang WANG, Hefei City (CN)

(73) Assignee: CXMT Corporation, Hefei City (CN)

(21) Appl. No.: 19/426,035

(22) Filed: Dec. 18, 2025

Related U.S. Application Data
(63) Continuation of application No. PCT/CN2025/091384, filed on Apr. 27, 2025.

(30) Foreign Application Priority Data
Nov. 4, 2024 (CN) 202411559807.9

(51) Int. Cl. H10B 12/00

(52) U.S. Cl. CPC H10B 12/09; H10B 12/315; H10B 12/482; H10B 12/485; H10B 12/50

(57) ABSTRACT

The forming method for a semiconductor structure includes following operations. A substrate is provided. The substrate includes a memory region and a boundary region sequentially adjacent to each other. An initial conductive layer is formed on the substrate and is patterned to form multiple initial bit line structures and an initial bit line contact layer. An etching mask provided with multiple first openings is formed. The initial bit line structures and the initial bit line contact layer are patterned by employing the etching mask to form multiple bit line structures and multiple bit line contact pads. Bit line isolation structures are formed. Each bit line isolation structure includes a first isolation portion located between the bit line structures and a second isolation portion located between the bit line contact pads. A first width of the first isolation portion is greater than a second width of the second isolation portion.

### CROSS-REFERENCE TO RELATED APPLICATIONS

This application is a continuation of International Patent Application No. PCT/CN2025/091384 filed on April 27, 2025, which claims priority to Chinese Patent Application No. 202411559807.9 filed on November 4, 2024. The disclosures of the above-referenced application are hereby incorporated by reference in their entirety.

### BACKGROUND

With development of the electronic industry and a requirement of a user, an electronic device is designed to be small in size and high in performance. In this case, a memory employed in the electronic device is also required to be highly integrated and have high performance.

To improve the degree of integration of the memory, the pattern line width of a semiconductor structure gradually decreases. However, an increase in the integration density of the semiconductor structure may cause a deterioration in the reliability of the semiconductor structure. In addition, with high development of the electronic industry, a demand for a highly reliable semiconductor structure is increasing. Therefore, many studies are underway to achieve the highly reliable semiconductor structure.

### SUMMARY

Embodiments of the present disclosure relate to the field of semiconductor technologies, and in particular, to a semiconductor structure and a forming method therefor.

According to a first aspect of the embodiments of the present disclosure, a forming method for a semiconductor structure is provided, including the following: A substrate is provided. The substrate includes a memory region and a boundary region sequentially adjacent to each other, and the memory region includes an array region and a dummy region. An initial conductive layer is formed on the substrate. The initial conductive layer in the memory region is patterned to form multiple initial bit line structures and the initial conductive layer in the boundary region is retained to form an initial bit line contact layer. The multiple initial bit line structures extend in a first direction and are arranged at intervals in a second direction. An etching mask provided with multiple first openings is formed. The multiple first openings expose a part of the initial bit line structures in the dummy region and a part of the initial bit line contact layer in the boundary region. The initial bit line structures and the initial bit line contact layer are patterned by employing the etching mask to form multiple bit line structures and multiple bit line contact pads. Bit line isolation structures are formed. Each of the bit line isolation structures includes a first isolation portion located between the bit line structures and a second isolation portion located between the bit line contact pads, and a first width of the first isolation portion is greater than a second width of the second isolation portion.

According to a second aspect of the embodiments of the present disclosure, a semiconductor structure is provided, including the following: a substrate, where the substrate includes a memory region and a boundary region sequentially adjacent to each other, and the memory region includes an array region and a dummy region; multiple bit line structures located in the memory region, where the multiple bit line structures extend in a first direction and are arranged at intervals in a second direction, and the multiple bit line structures include first bit lines and second bit lines arranged alternately in the second direction; multiple bit line contact pads located in the boundary region, where the multiple bit line contact pads are arranged at intervals in the second direction, and the second bit lines extend to the dummy region and are connected to the bit line contact pads in a one-to-one correspondence; and bit line isolation structures located in the dummy region and the boundary region, where each of the bit line isolation structures includes a first isolation portion located between the second bit lines and a second isolation portion located between the bit line contact pads, and a first width of the first isolation portion is greater than a second width of the second isolation portion.

### BRIEF DESCRIPTION OF DRAWINGS

To describe the technical solutions in the embodiments of the present disclosure or the conventional technologies more clearly, the following briefly describes the accompanying drawings required for describing the embodiments or the conventional technologies. Clearly, the accompanying drawings in the following description show merely some embodiments of the present disclosure, and a person of ordinary skill in the art may still derive other accompanying drawings from these accompanying drawings without creative efforts.

FIG. 1 is a flowchart of a forming method for a semiconductor structure according to an example embodiment;

FIG. 2A to FIG. 11C are schematic top views and schematic cross-sectional views of a semiconductor structure in a forming procedure according to an embodiment of the present disclosure, where FIG. 2A, FIG. 3A, FIG. 4A, FIG. 5A, FIG. 6A, FIG. 7A, FIG. 8A, FIG. 9A, FIG. 10A, and FIG. 11A are schematic top views of the semiconductor structure, and FIG. 2B, FIG. 3B, FIG. 4B, FIG. 5B, FIG. 6B, FIG. 7B, FIG. 8B, FIG. 9B, FIG. 10B, and FIG. 11B, and FIG. 2C, FIG. 3C, FIG. 4C, FIG. 5C, FIG. 6C, FIG. 7C, FIG. 8C, FIG. 9C, FIG. 10C, and FIG. 11C are schematic cross-sectional views of the semiconductor structure; and

FIG. 12 is a schematic top view of another semiconductor structure according to an embodiment of the present disclosure.

### DESCRIPTION OF EMBODIMENTS

The technical solutions of the present disclosure are further described below in detail with reference to the accompanying drawings and the embodiments. Although example implementation methods of the present disclosure are shown in the accompanying drawings, it should be understood that the present disclosure may be implemented in various forms without being limited by the implementations described herein. Instead, these implementations are provided to develop a more thorough understanding of the present disclosure and to fully convey the scope of the present disclosure to a person skilled in the art.

In the following paragraphs, the present disclosure is described more specifically by way of example with reference to the accompanying drawings. The advantages and features of the present disclosure will be clearer from the following description and claims. It should be noted that the accompanying drawings are presented in a highly simplified form and are not drawn to exact scale, and are merely intended to conveniently and clearly assist in describing the embodiments of the present disclosure.

It may be understood that meanings of "on", "over", and "above" in the present disclosure should be understood in the broadest sense, so that "on" means that it is "on" something with no intermediate feature or layer (that is, directly on something), and further includes the meaning that it is "on" something with an intermediate feature or layer.

In the embodiments of the present disclosure, the terms "first", "second", "third", and the like are intended to distinguish between similar objects but do not necessarily describe a specific order or sequence.

In the embodiments of the present disclosure, the term "layer" refers to a material part including a region having the thickness. The layer may extend over the whole of a lower or upper structure, or may have a range smaller than the range of the lower or upper structure. In addition, the layer may be a region of a homogeneous or heterogeneous continuous structure whose thickness is less than the thickness of a continuous structure. For example, the layer may be located between the top surface and the bottom surface of the continuous structure, or the layer may be located between any horizontal surface pair at the top surface and the bottom surface of the continuous structure. The layer may extend horizontally, vertically, and/or along an inclined surface. The layer may include multiple sublayers.

It should be noted that the technical solutions described in the embodiments of the present disclosure may be randomly combined when there is no conflict.

A dynamic random access memory (DRAM) is taken as an example, and the DRAM is a volatile memory. The DRAM usually includes a memory region including memory cells and a peripheral region including logic control circuits. A typical memory cell includes one switch structure (e.g., a transistor) and one memory structure (e.g., a capacitor). The logic control circuit in the peripheral region may address each memory cell in the memory region by employing multiple columns of word lines (word lines) and multiple rows of bit lines (bit lines) passing through the memory region, and open the switch structure to electrically connect to the memory structure, to read, write, or access data. In advanced semiconductor manufacturing, a chip size of the DRAM can be greatly reduced by employing an architecture in which word lines are embedded. By employing this architecture, active regions of memory cells can be arranged at a dense spacing to obtain a higher cell density.

As a semiconductor structure including the logic control circuit and the memory cell is reduced to a smaller size, a technical obstacle faced by a patterning process is becoming more obvious. For example, in a current DRAM, because the size of the memory cell is reduced, it is difficult to form good electrical contact between the bit line and the logic control circuit. For example, to form an electrical connection between the bit line and a sense amplifier, a structure such as a bit line pad contact structure for electrically connecting the bit line needs to be formed. Due to a tight arrangement of the bit lines, the bit line pad contact structure may fail to effectively contact a corresponding bit line, resulting in an open circuit of a line. Alternatively, due to an alignment deviation, the bit line pad contact structure may be in contact with a non-corresponding structure (e.g., a node contact structure or a non-corresponding bit line), resulting in a short circuit of a line. Both the open circuit of the line and the short circuit of the line may result in data read errors, degrading memory reliability.

Based on this, to resolve the foregoing problem, an embodiment of the present disclosure provides a forming method for a semiconductor structure.

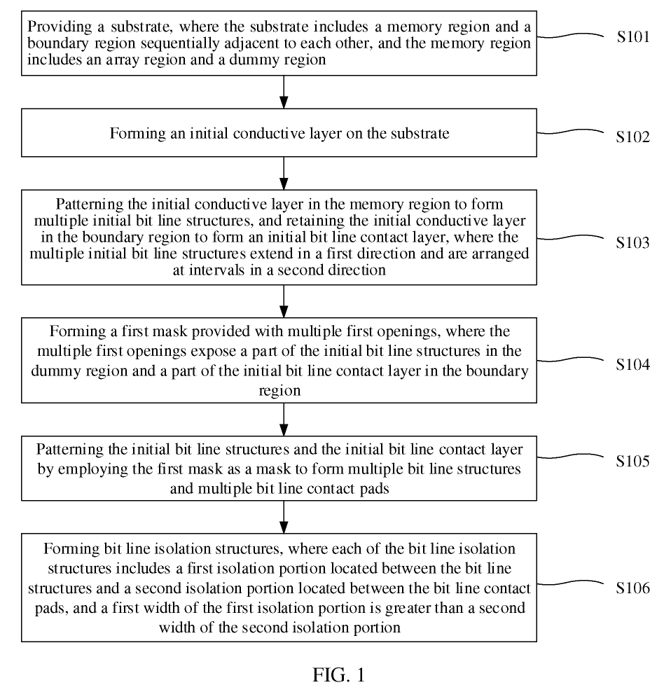

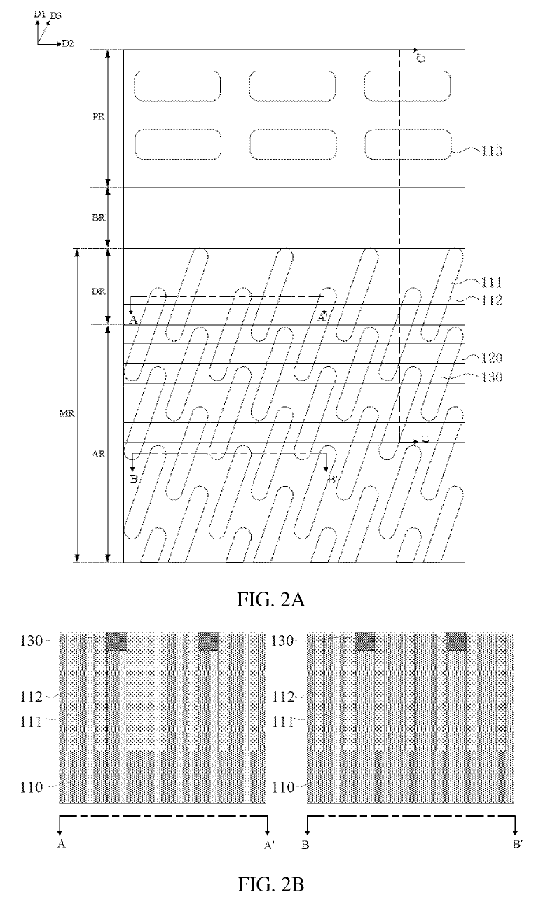

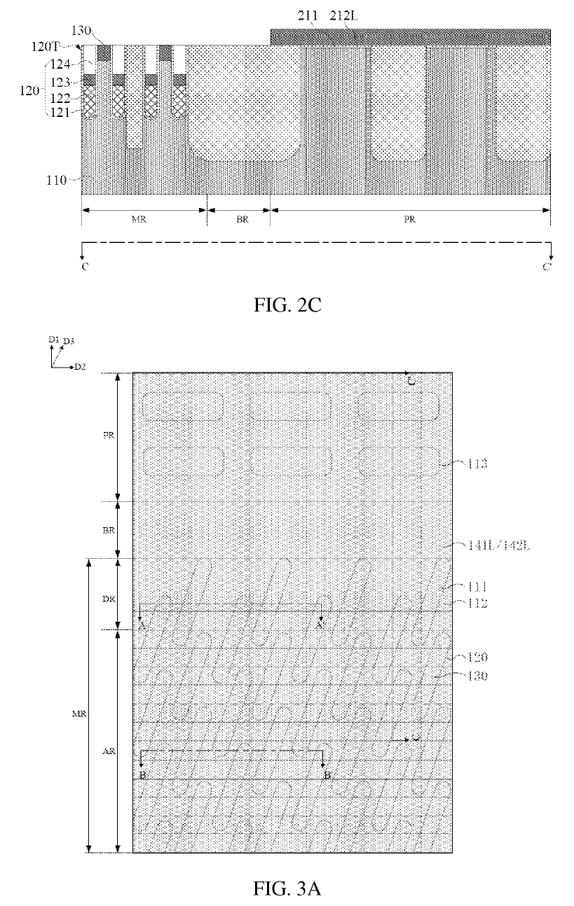

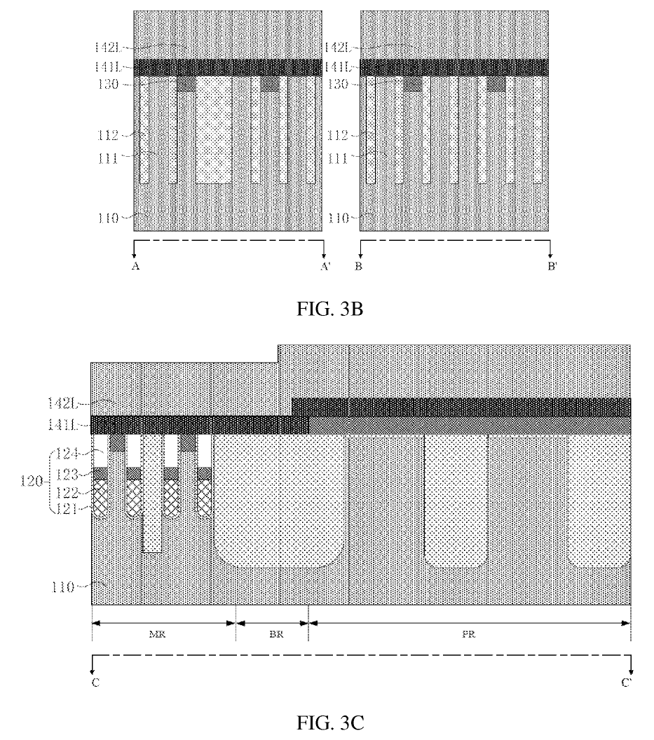

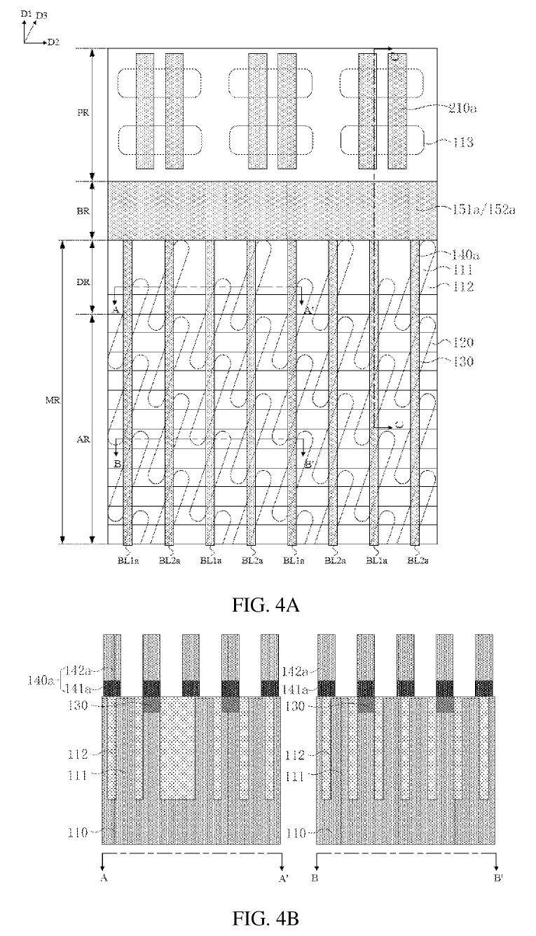

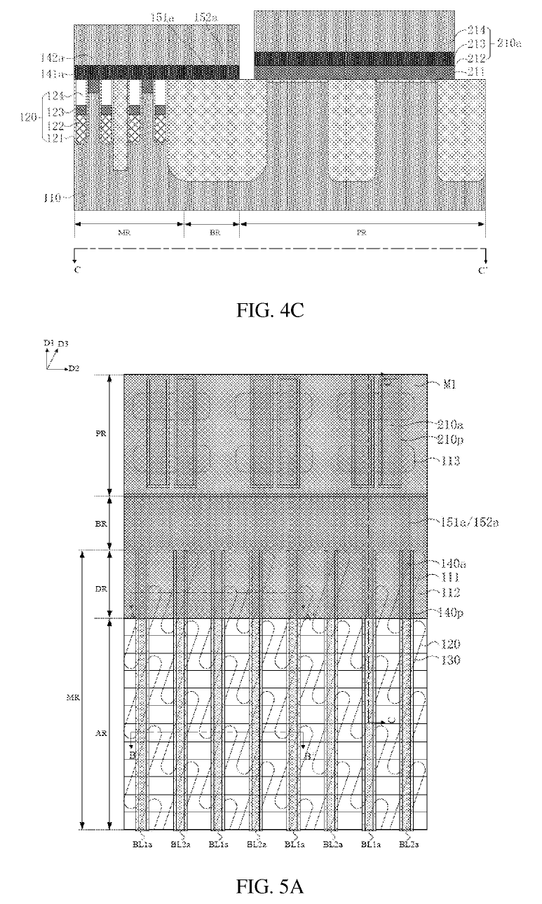

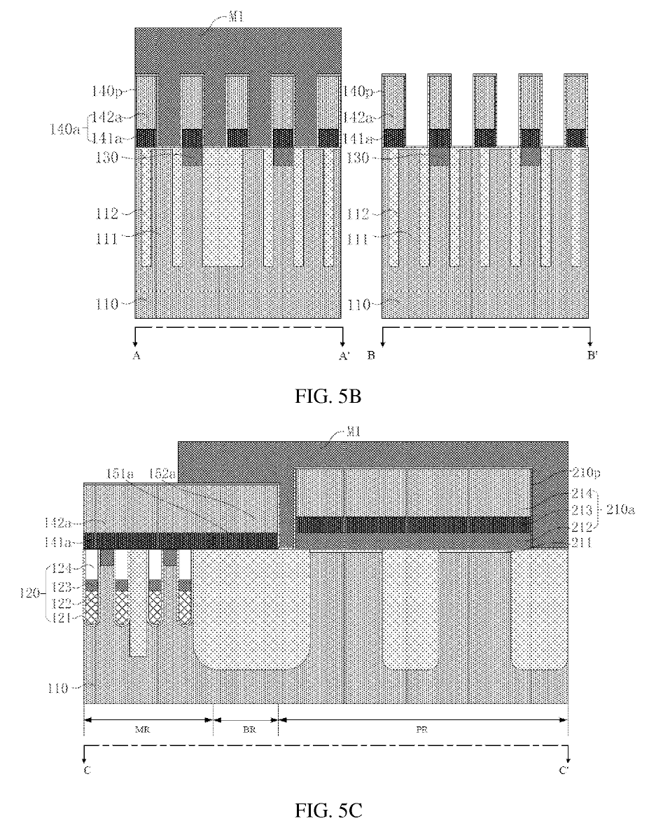

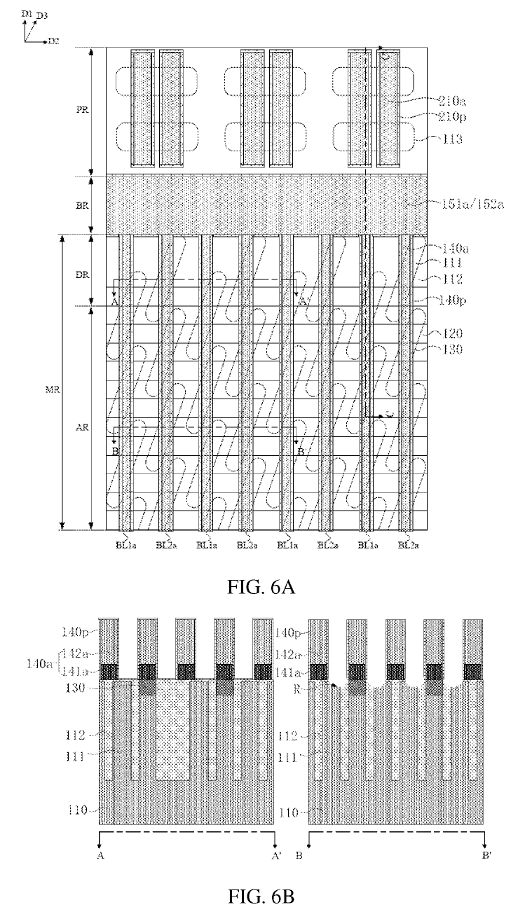

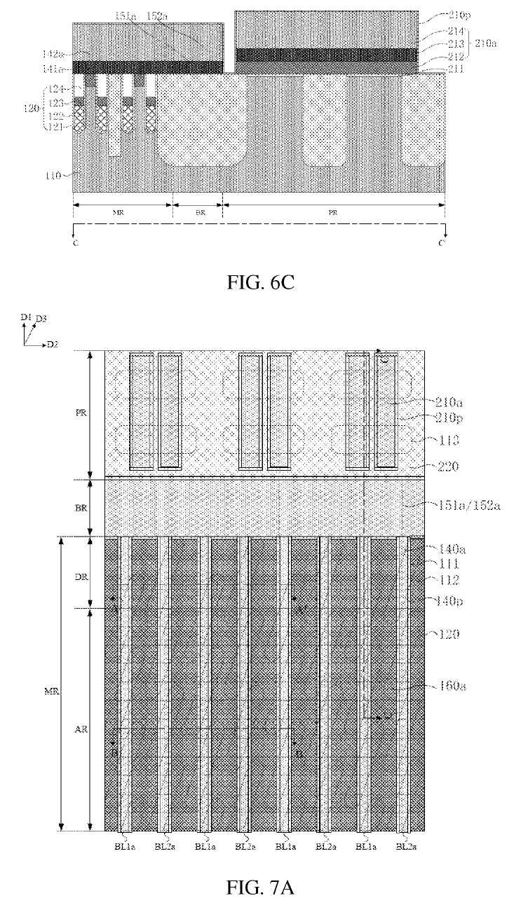

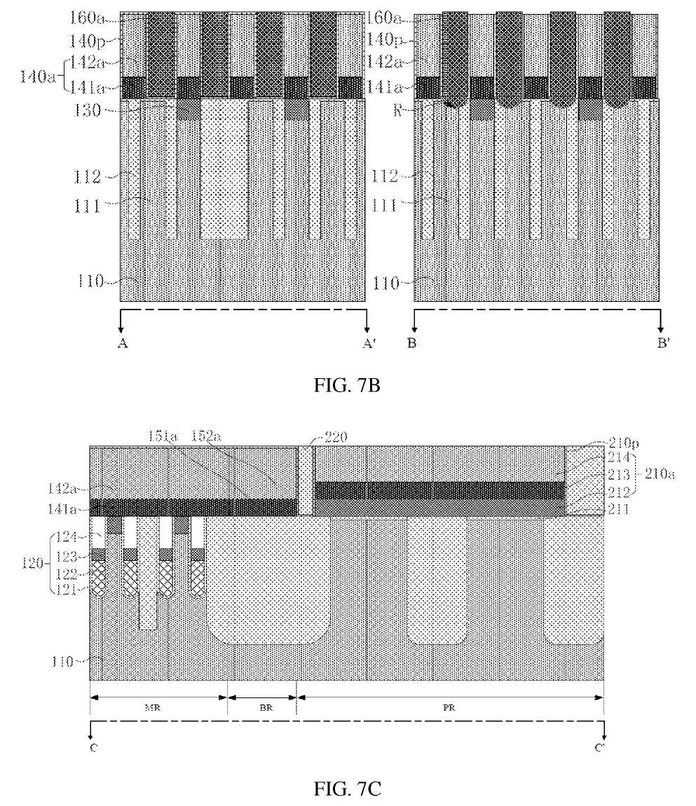

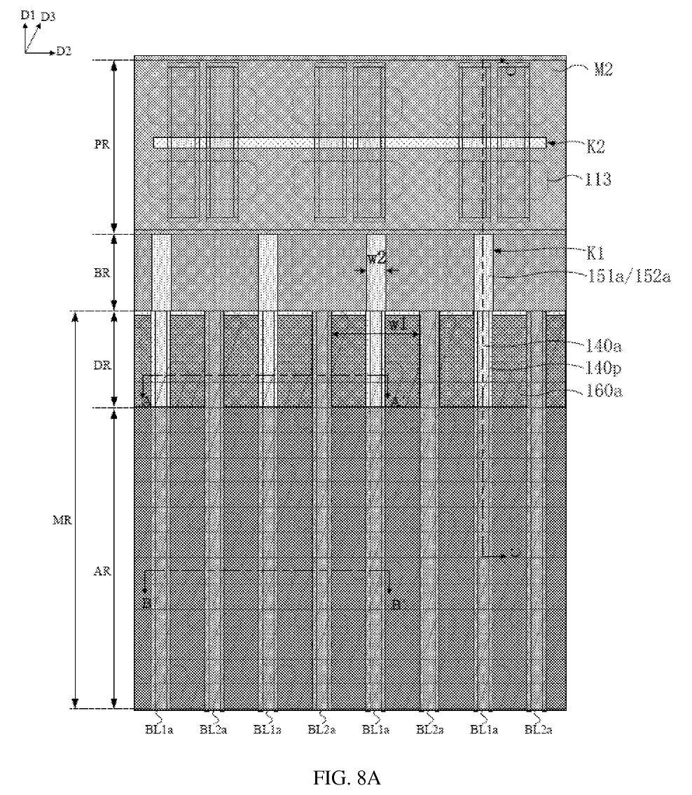

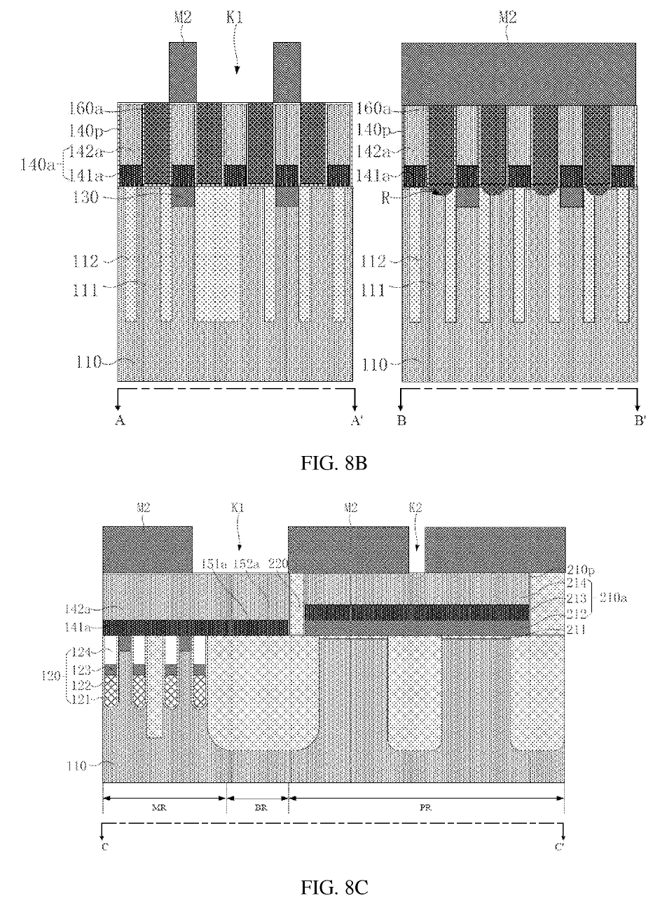

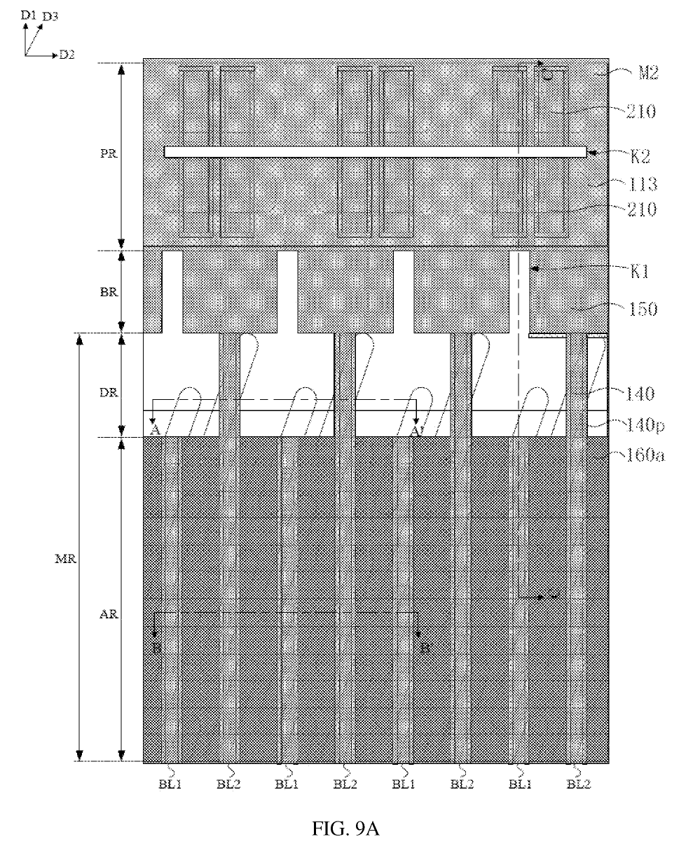

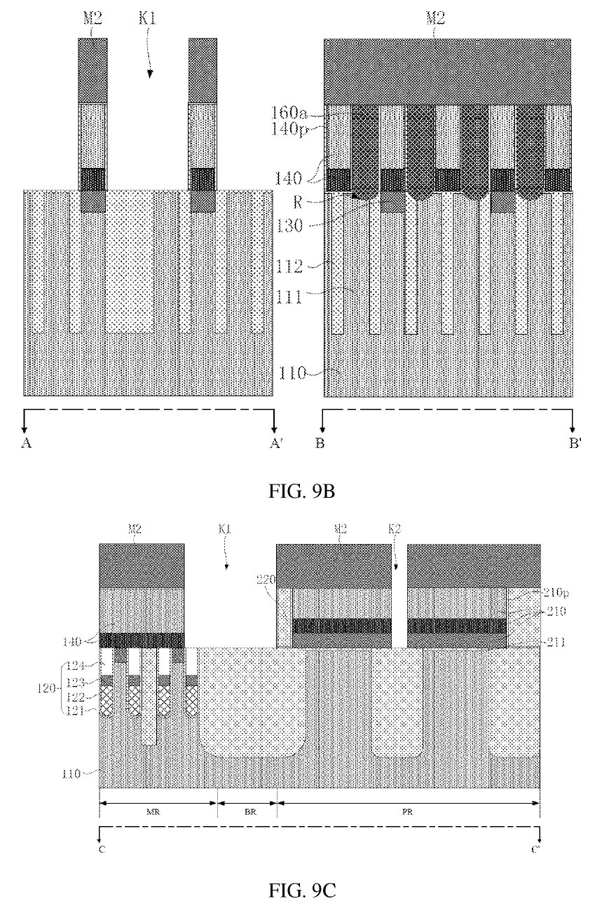

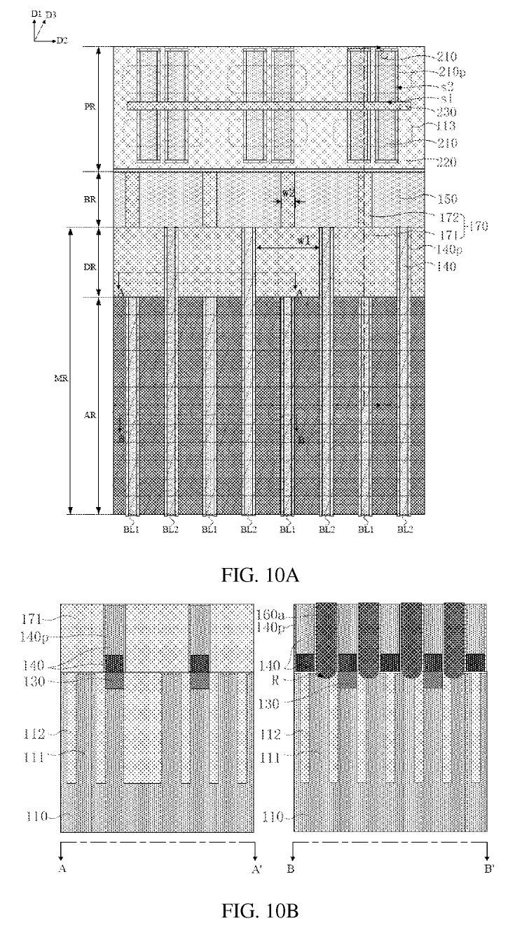

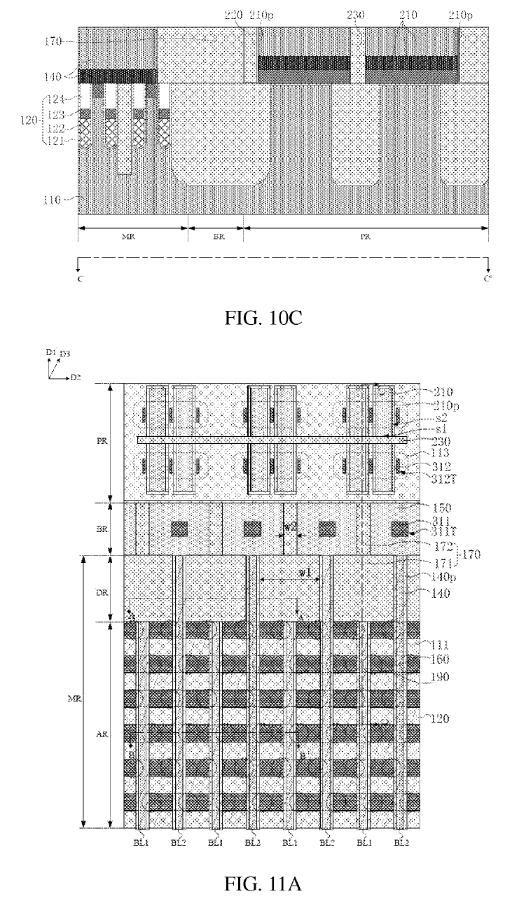

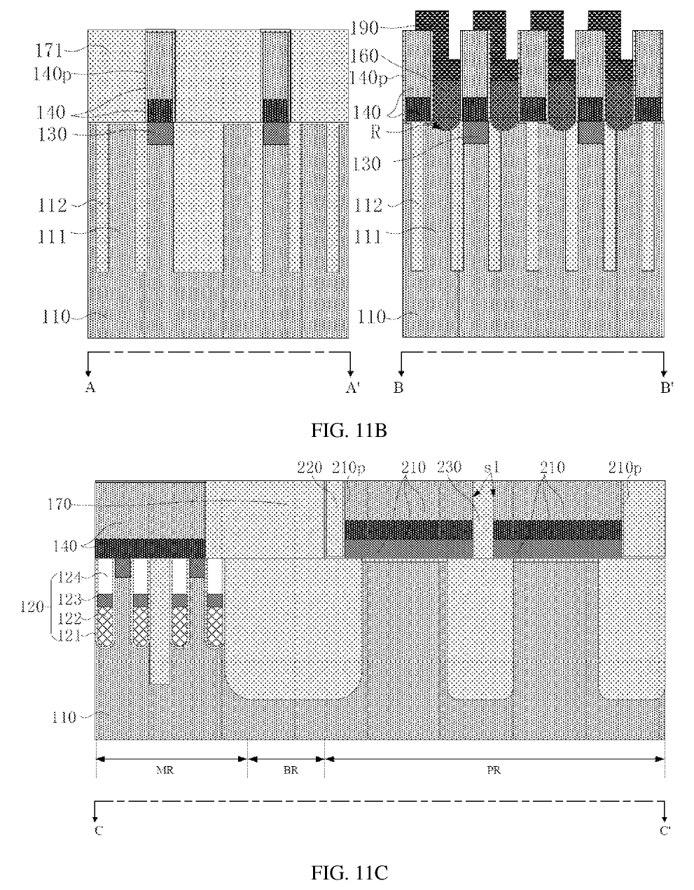

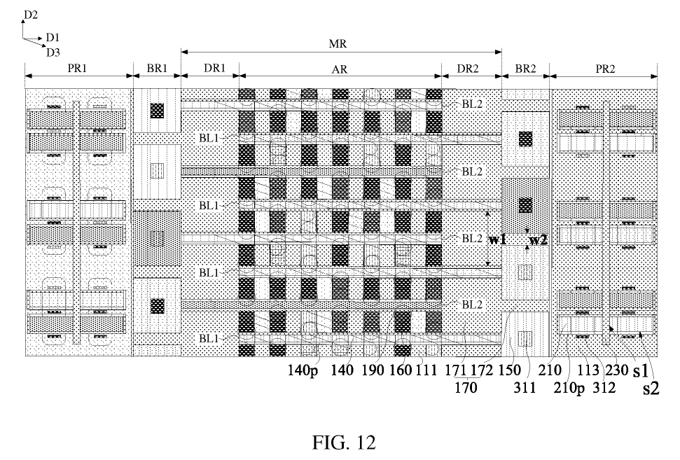

FIG. 1 is a flowchart of a forming method for a semiconductor structure according to an embodiment of the present disclosure; FIG. 2A to FIG. 11C are schematic top views and schematic cross-sectional views of a semiconductor structure in a forming procedure according to an embodiment of the present disclosure, where FIG. 2A, FIG. 3A, FIG. 4A, FIG. 5A, FIG. 6A, FIG. 7A, FIG. 8A, FIG. 9A, FIG. 10A, and FIG. 11A are schematic top views of the semiconductor structure, FIG. 2B, FIG. 3B, FIG. 4B, FIG. 5B, FIG. 6B, FIG. 7B, FIG. 8B, FIG. 9B, FIG. 10B, and FIG. 11B are schematic cross-sectional views of the semiconductor structure along cross-sections A-A' and B-B' in the schematic top views, and FIG. 2C, FIG. 3C, FIG. 4C, FIG. 5C, FIG. 6C, FIG. 7C, FIG. 8C, FIG. 9C, FIG. 10C, and FIG. 11C are schematic cross-sectional views of the semiconductor structure along a cross-section C-C' in the schematic top views; and FIG. 12 is a schematic top view of another semiconductor structure according to an embodiment of the present disclosure. The following describes in detail the forming method for a semiconductor structure provided in this embodiment of the present disclosure with reference to FIG. 1 to FIG. 12. It may be understood that in FIG. 2A to FIG. 11A and FIG. 12, a first direction D1, a second direction D2, and a third direction D3 are horizontal directions parallel to the plane in which a substrate 110 is located, and the first direction D1 intersects the second direction D2, for example, the first direction D1 may be perpendicular to the second direction D2, and the third direction D3 is a direction intersecting both the first direction D1 and the second direction D2.

As shown in FIG. 1, the forming method for a semiconductor structure includes at least the following steps.

In the step of S101, a substrate is provided, where the substrate includes a memory region and a boundary region sequentially adjacent to each other, and the memory region includes an array region and a dummy region.

In the step of S102, an initial conductive layer is formed on the substrate.

In the step of S103, the initial conductive layer in the memory region is patterned to form multiple initial bit line structures, and the initial conductive layer in the boundary region is retained to form an initial bit line contact layer, where the multiple initial bit line structures extend in the first direction and are arranged at intervals in the second direction.

In the step of S104, an etching mask provided with multiple first openings is formed, where the multiple first openings expose a part of the initial bit line structures in the dummy region and a part of the initial bit line contact layer in the boundary region.

In the step of S105, the initial bit line structures and the initial bit line contact layer are patterned by employing the etching mask to form multiple bit line structures and multiple bit line contact pads.

In the step of S106, bit line isolation structures are formed, where each of the bit line isolation structures includes a first isolation portion located between the bit line structures and a second isolation portion located between the bit line contact pads, and a first width of the first isolation portion is greater than a second width of the second isolation portion.

It should be understood that the steps shown in FIG. 1 are not exclusive, and another step may be performed before, after, or between any steps in the operations shown. The sequence of the steps shown in FIG. 1 may be adjusted according to an actual requirement.

In the forming method for a semiconductor structure provided in the present disclosure, according to a first aspect, the dummy region and the boundary region are disposed, to form the bit line contact pads located in the boundary region and a part of the bit line structure extending to the dummy region, thereby reducing arrangement density of the bit line contact pads, increasing an effective contact area of the bit line contact pad, and increasing alignment between the bit line contact pad and a subsequently formed bit line pad contact structure. According to a second aspect, a single etching step is performed on the initial bit line structure and the initial bit line contact layer by employing the etching mask provided with the first opening, thereby effectively improving manufacturing process efficiency of the semiconductor structure, and ensuring an electrical connection between the bit line structure and a corresponding bit line contact pad. According to a third aspect, the first isolation portion located between the bit line structures has a larger first width by forming a "convex"-shaped bit line isolation structure, thereby effectively avoiding a short circuit of a line between the bit line pad contact structure and a non-corresponding structure. The second isolation portion located between the bit line contact pads has a smaller second width, thereby increasing occupation space of the bit line contact pads in the boundary region, and improving a process window of the bit line pad contact structure.

Referring to FIG. 2A, FIG. 2B, and FIG. 2C, FIG. 2B is a schematic cross-sectional view of a semiconductor structure cut along cross-sections A-A' and B-B' in the schematic top view shown in FIG. 2A, and FIG. 2C is a schematic cross-sectional view of a semiconductor structure cut along a cross-section C-C' in the schematic top view shown in FIG. 2A. The substrate 110 may be divided into the memory region MR, the boundary region BR, and a peripheral region PR sequentially adjacent to each other. The boundary region BR is located on at least one outside of the memory region MR, and the peripheral region PR is located on at least one outside of the boundary region BR. For example, the boundary region BR surrounds the memory region MR, and the peripheral region PR surrounds the boundary region BR. The memory region MR may be divided into the array region AR and the dummy region DR located on at least one outside of the array region AR.

Referring to FIG. 2A and FIG. 2B, array active regions 111 and a shallow trench isolation structure 112 separating the array active regions 111 are provided in the memory region MR of the substrate 110. The array active regions 111 are arranged in an array in the first direction D1 and the second direction D2, and each array active region 111 extends in the third direction D3 in the schematic top view. The shallow trench isolation structure 112 is an integrated structure located in the memory region MR, the boundary region BR, and the peripheral region PR, and the shallow trench isolation structure 112 located in different regions may have different depths. For example, the bottom surface of the shallow trench isolation structure 112 located in the peripheral region PR and the boundary region BR may be lower than the bottom surface of the shallow trench isolation structure 112 located in the memory region MR. Peripheral active regions 113 separated by the shallow trench isolation structure 112 are further provided in the peripheral region PR in the substrate 110. The array active regions 111 may be located in the array region AR and the dummy region DR of the memory region MR, or the array active regions 111 may be located only in the array region AR of the memory region MR. The array region AR is an region employed to form a valid memory cell, the dummy region DR is an region employed to form a dummy memory cell, the dummy memory cell is a memory cell not employed for actual work, and the dummy memory cell is employed to reduce the impact caused by an actual deviation of a manufacturing process.

The material of the substrate 110 includes a semiconductor material, e.g., a single-element semiconductor material (e.g., silicon (Si) or germanium (Ge)), a III-V compound semiconductor material (e.g., gallium nitride (GaN), gallium arsenide (GaAs), or indium phosphide (InP)), a II-VI compound semiconductor material (e.g., zinc sulfide (ZnS), cadmium sulfide (CdS), or cadmium telluride (CdTe)), an organic semiconductor material, or another semiconductor material known in the art. The material of the shallow trench isolation structure 112 includes one or more of an insulating material such as silicon oxide, silicon nitride, or silicon oxynitride. The shallow trench isolation structure 112 may be in a single-layer structure or a multi-layer structure. For example, the shallow trench isolation structure 112 may be in a multi-layer structure formed by silicon nitride-silicon oxide-silicon nitride (NON).

In some embodiments, the substrate 110 further includes a substrate protective layer located on the top surfaces of the array active regions 111 and the shallow trench isolation structure 112. The materials of the substrate protective layer and the shallow trench isolation structure 112 are the same.

Referring to FIG. 2A and FIG. 2C, embedded word lines 120 are further formed in the substrate 110, the embedded word lines 120 are formed in the memory region MR, the embedded word lines 120 extend in the second direction D2 and are arranged at intervals in the first direction D1, and intersect the array active regions 111, and each array active region 111 intersects two embedded word lines 120. A word line trench 120T is formed in the substrate 110, and a gate dielectric layer 121, a gate conductive layer, and a gate cover layer 124 are sequentially formed in the word line trench 120T to form the embedded word line 120. The gate conductive layer may be in a single-layer structure or a multi-layer structure. For example, the gate conductive layer may include a first gate conductive layer 122 and a second gate conductive layer 123, and a work function of the second gate conductive layer 123 is lower than a work function of the first gate conductive layer 122, which can reduce a gate-induced drain leakage current (GIDL, gate-induced drain leakage). The material of the gate conductive layer may be a conductive material including a semiconductor material (e.g., doped polysilicon), metal (e.g., tungsten (W), titanium (Ti), tantalum (Ta), ruthenium (Ru), cobalt (Co), and molybdenum (Mo)), a conductive metal nitride (e.g., titanium nitride and tantalum nitride), and a metal semiconductor compound (e.g., tungsten silicide, cobalt silicide, and titanium silicide). In an example, the material of the first gate conductive layer 122 is metal, and the material of the second gate conductive layer 123 is doped polysilicon. The material of the gate dielectric layer 121 may be silicon oxide, silicon nitride, silicon oxynitride, or the like. The gate dielectric layer 121 may be formed on the bottom and the sidewall of the word line trench 120T by employing an in-situ steam generation (In-Situ Steam Generation, ISSG) process. Alternatively, the gate dielectric layer 121 may be formed by employing an atomic layer deposition process, a plasma vapor deposition process, or a rapid thermal oxidation (Rapid Thermal Oxidation, RTO) process. The material of the gate cover layer 124 includes an insulating material such as silicon nitride or silicon oxynitride.

Bit line contact plugs 130 are further formed in the substrate 110. The bit line contact plugs 130 may be disposed in contact with the array active regions 111 in a one-to-one correspondence. The bit line contact plug 130 is located in the middle of the array active region 111, the bottom surface of the bit line contact plug 130 is lower than the top surface of the array active region 111, and the top surface of the bit line contact plug 130 may be flush with the top surface of the array active region 111. The material of the bit line contact plug 130 may include a conductive material such as doped polysilicon.

Referring to FIG. 2A and FIG. 2C, an initial first conductive layer 212L may be further formed on the peripheral region PR of the substrate 110, and the initial first conductive layer 212L may be formed synchronously with the bit line contact plug 130. Before the initial first conductive layer 212L and the bit line contact plug 130 are formed, the method further includes the following: A peripheral dielectric layer 211 is formed on the substrate 110. The material of the peripheral dielectric layer 211 may include a high dielectric constant material, silicon oxide, and the like. The high dielectric constant material is one or more of hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminium oxide, lead scandium tantalum oxide, and lead zinc niobate.

Referring to FIG. 3A, FIG. 3B, and FIG. 3C, FIG. 3B is a schematic cross-sectional view of a semiconductor structure cut along cross-sections A-A' and B-B' in the schematic top view shown in FIG. 3A, and FIG. 3C is a schematic cross-sectional view of a semiconductor structure cut along a cross-section C-C' in the schematic top view shown in FIG. 3A. An initial conductive layer 141L is formed on the memory region MR, the boundary region BR, and the peripheral region PR of the substrate 110. The material of the initial conductive layer 141L may be a conductive material such as a semiconductor material, metal, a conductive metal nitride, or a metal semiconductor compound. The initial conductive layer 141L may be in a single-layer structure or a multi-layer structure. For example, the initial conductive layer 141L may be in a multi-layer structure including the metal semiconductor compound and the metal. The metal semiconductor compound (e.g., tungsten silicide, cobalt silicide, or titanium silicide) can reduce contact resistance between the metal and the bit line contact plug 130. An initial cover layer 142L may be further formed on the initial conductive layer 141L. The material of the initial cover layer 142L is an insulating material such as silicon nitride.

Referring to FIG. 4A, FIG. 4B, and FIG. 4C, FIG. 4B is a schematic cross-sectional view of a semiconductor structure cut along cross-sections A-A' and B-B' in the schematic top view shown in FIG. 4A, and FIG. 4C is a schematic cross-sectional view of a semiconductor structure cut along a cross-section C-C' in the schematic top view shown in FIG. 4A. The initial conductive layer 141L in the memory region MR is patterned to form multiple initial bit line structures 140a. The initial bit line structure 140a may include an initial bit line conductive layer 141a and an initial bit line cover layer 142a that are stacked. The initial bit line conductive layer 141a is obtained from the initial conductive layer 141L through patterning, and the initial bit line cover layer 142a is obtained from the initial cover layer 142L through patterning. The initial conductive layer 141L and the initial cover layer 142L in the boundary region BR are retained to form an initial bit line contact layer 151a and an initial contact cover layer 152a, the multiple initial bit line structures 140a extend in the first direction D1 and are arranged at intervals in the second direction D2, and the initial bit line contact layer 151a is connected to an end portion of the initial bit line conductive layer 141a of each initial bit line structure 140a. A self-aligned double patterning (SADP, Self-Aligned Double Patterning) process may be employed to form the multiple initial bit line structures 140a.

Referring to FIG. 4A and FIG. 4C, when the initial conductive layer 141L in the memory region MR is patterned to form the multiple initial bit line structures 140a, the method further includes the following: The initial conductive layer 141L in the peripheral region PR is patterned to form peripheral gates 210a, where the initial bit line contact layer 151a is spaced from the peripheral gate 210a. The peripheral gate 210a may include a first peripheral gate conductive layer 212, a second peripheral gate conductive layer 213, and a peripheral gate cover layer 214 that are stacked. The first peripheral gate conductive layer 212 is obtained by patterning the initial first conductive layer 212L, the second peripheral gate conductive layer 213 is obtained by patterning the initial conductive layer 141L, and the peripheral gate cover layer 214 is obtained by patterning the initial cover layer 142L.

In some embodiments, one peripheral gate 210a may correspond to at least two peripheral active regions 113. To be specific, the projection of the one peripheral gate 210a on the substrate 110 may intersect the projections of the at least two peripheral active regions 113 on the substrate 110, and the one peripheral gate 210a is configured to form at least two peripheral transistors.

Referring to FIG. 5A, FIG. 5B, and FIG. 5C, FIG. 5B is a schematic cross-sectional view of a semiconductor structure cut along cross-sections A-A' and B-B' in the schematic top view shown in FIG. 5A, and FIG. 5C is a schematic cross-sectional view of a semiconductor structure cut along a cross-section C-C' in the schematic top view shown in FIG. 5A. After the initial conductive layer 141L in the memory region MR is patterned to form the multiple initial bit line structures 140a and the peripheral gates 210a, the method further includes the following: A peripheral gate protective layer 210p is formed on the sidewall of each of the peripheral gates 210a, and a bit line protective layer 140p is formed on the sidewall of each of the initial bit line structures 140a. The peripheral gate protective layer 210p and the bit line protective layer 140p are formed integrally, and further cover a part of the surface of the substrate 110.

In some embodiments, referring to FIG. 5A, FIG. 5B, and FIG. 5C, after the peripheral gate protective layer 210p and the bit line protective layer 140p are formed, the method further includes the following: A peripheral mask M1 is formed, where the peripheral mask M1 covers the dummy region DR, the boundary region BR, and the peripheral region PR. Referring to FIG. 6A, FIG. 6B, and FIG. 6C, FIG. 6B is a schematic cross-sectional view of a semiconductor structure cut along cross-sections A-A' and B-B' in the schematic top view shown in FIG. 6A, and FIG. 6C is a schematic cross-sectional view of a semiconductor structure cut along a cross-section C-C' in the schematic top view shown in FIG. 6A. The bit line protective layer 140p located on the substrate 110 in the array region AR is removed by employing the peripheral mask M1, to expose the substrate 110 in the array region AR, and then the peripheral mask M1 is removed. The material of the peripheral mask M1 may be photoresist and is configured to protect the substrate 110 in a region other than the array region AR. Because the peripheral mask M1 does not cover the array region AR, an etching process may be employed to remove a part of the bit line protective layer 140p and a part of the substrate 110 between the initial bit line structures 140a in the array region AR, to form a recess R, and the recess R exposes an end portion of the array active region 111 in the substrate 110. The etching process includes a dry etching process or a wet etching process, and dry etching includes at least any one of reactive ion etching (RIE, Reaction Ion Etching), inductively coupled plasma etching (ICP, Inductively Coupled Plasma), or high-density plasma (HDP, High-Density Plasma) etching. The bit line protective layer 140p located on the substrate 110 between the initial bit line structures 140a in the array region AR may be removed by employing the dry etching process to expose the substrate 110, and the bit line protective layer 140p located on the top of the initial bit line structure 140a in the array region AR may be simultaneously removed. Then, the recess R on the surface of the substrate 110 is formed by employing the wet etching process. For a part of the initial bit line structure 140a located in the array region AR, only the bit line protective layer 140p on the sidewall is retained. For a part of the initial bit line structure 140a located in the dummy region DR, the bit line protective layer 140p located on the sidewall and the top is retained.

Referring to FIG. 7A, FIG. 7B, and FIG. 7C, FIG. 7B is a schematic cross-sectional view of a semiconductor structure cut along cross-sections A-A' and B-B' in the schematic top view shown in FIG. 7A, and FIG. 7C is a schematic cross-sectional view of a semiconductor structure cut along a cross-section C-C' in the schematic top view shown in FIG. 7A. After the peripheral mask M1 is removed, a peripheral isolation layer 220 is filled in a gap between the peripheral gates 210a in the peripheral region PR, and an initial contact layer 160a is filled between the multiple initial bit line structures 140a. The top surface of the initial contact layer 160a may be controlled to be flush with that of the initial bit line structure 140a by employing a planarization process. The material of the initial contact layer 160a includes a conductive material such as a semiconductor material (e.g., doped polysilicon) and a metal semiconductor compound (e.g., tungsten silicide, cobalt silicide, titanium silicide). In the array region AR, the initial contact layer 160a is in direct contact with the array active region 111 in the substrate 110 exposed by the recess R, and the initial contact layer 160a in the array region AR is configured to form node contact structures for electrically connecting the array active regions 111 and memory structures. In the dummy region DR, the initial contact layer 160a contacts the bit line protective layer 140p retained on the surface of the substrate 110 and is not electrically connected to the substrate 110, and the initial contact layer 160a in the dummy region DR is configured to form a dummy node contact structure. On the dummy region DR, no memory structure may be formed, or a memory structure not electrically connected to the substrate 110 may be formed. Usually, due to a manufacturing process error of a structure such as the array active region 111, a memory cell with poor performance is easily formed in the dummy region DR. By disposing the dummy node contact structure in the dummy region DR, the impact of the memory cell with poor performance on the semiconductor structure can be avoided.

Referring to FIG. 8A, FIG. 8B, and FIG. 8C, FIG. 8B is a schematic cross-sectional view of a semiconductor structure cut along cross-sections A-A' and B-B' in the schematic top view shown in FIG. 8A, and FIG. 8C is a schematic cross-sectional view of a semiconductor structure cut along a cross-section C-C' in the schematic top view shown in FIG. 8A. An etching mask M2 provided with multiple first openings K1 is formed, and the multiple first openings K1 expose a part of the initial bit line structures 140a in the dummy region DR and a part of the initial bit line contact layer 151a and the initial contact cover layer 152a in the boundary region BR. A first width w1 of the first opening K1 located in the dummy region DR is greater than a second width w2 of the first opening K1 located in the boundary region BR.

In some embodiments, the first opening K1 is a "convex" shaped opening from the dummy region DR toward the boundary region BR, and may be formed by a first rectangular opening located in the dummy region DR and a second rectangular opening located in the boundary region BR that are connected to each other. In addition, the length of the first rectangular opening in the first direction D1 is greater than or equal to the length of the second rectangular opening in the first direction D1, and a first width w1 of the first rectangular opening in the second direction D2 is greater than a second width w2 of the second rectangular opening in the second direction D2. In some examples, the first width w1 of the first opening K1 located in the dummy region DR is equal to a spacing between the initial bit line structures 140a spaced apart from each other, that is, equal to the width of one initial bit line structure 140a plus two adjacent initial contact layers 160a. The first opening K1 located in the dummy region DR exposes the initial contact layer 160a in the dummy region DR. The second width w2 of the first opening K1 located in the boundary region BR is substantially equal to the width of one initial bit line structure 140a, for example, the ratio of the second width w2 to the width of the one initial bit line structure 140a ranges from 0.8 to 1.5.

Referring to FIG. 9A, FIG. 9B, and FIG. 9C, FIG. 9B is a schematic cross-sectional view of a semiconductor structure cut along cross-sections A-A' and B-B' in the schematic top view shown in FIG. 9A, and FIG. 9C is a schematic cross-sectional view of a semiconductor structure cut along a cross-section C-C' in the schematic top view shown in FIG. 9A. Two end surfaces of the first opening K1 in the first direction D1 are respectively adjacent to an interfacial surface between the peripheral region PR and the boundary region BR, and an interfacial surface between the dummy region DR and the array region AR. That the initial bit line structures 140a and the initial bit line contact layer 151a are patterned by employing the etching mask M2 includes the following: The initial bit line structures 140a are etched along the first openings K1 to form multiple bit line structures 140, where the multiple bit line structures 140 extend alternately to the dummy region DR. The initial bit line contact layer 151a is etched along the first openings K1 to cut the initial bit line contact layer 151a in the first direction D1, to form multiple bit line contact pads 150 arranged at intervals in the second direction D2. The method further includes the following: The initial contact layer 160a is etched along the first opening K1 to remove the initial contact layer 160a in the dummy region DR. By removing the initial contact layer 160a in the dummy region DR, a case in which a bit line and a memory structure are shorted caused by a position offset of a subsequently formed bit line pad contact structure can be avoided. By skipping forming the dummy node contact structure, an electrical connection abnormality between the dummy node contact structure and the substrate caused by a process error can be avoided, and a process window of the bit line pad contact structure can be further improved.

In some embodiments, a second opening K2 exposes a part of the peripheral gates 210a in the peripheral region PR, and when the initial bit line structures 140a and the initial bit line contact layer 151a are patterned by employing the etching mask M2, the method further includes the following: Each of the peripheral gates 210a is patterned by employing the etching mask M2 to form two opposite peripheral sub-gates 210, where an arrangement direction of the two opposite peripheral sub-gates 210 is an extension direction of the peripheral gates 210a. The extension direction of the peripheral gate 210a may be the first direction D1 or the second direction D2. In FIG. 9A, that the extension direction of the peripheral gate 210a is the first direction D1 is taken as an example. The second opening K2 may be configured to pattern multiple peripheral gates 210a arranged in parallel, and an extension direction of the second opening K2 is perpendicular to the extension direction of the peripheral gates 210a. For example, the peripheral gates 210a extend in the first direction D1, and the multiple peripheral gates 210a are etched by employing the second opening K2 extending in the second direction D2, so that each of the peripheral gates 210a is patterned as the two peripheral sub-gates 210 opposite to each other in the first direction D1. The width of the second opening K2 in the first direction D1 is less than a spacing between two peripheral active regions 113 intersecting the peripheral gate 210a, for example, the width of the second opening K2 in the first direction D1 is less than one third of the spacing between the two peripheral active regions 113 intersecting the peripheral gate 210a. By employing the etching mask M2 provided with the second opening K2 to perform patterned processing on the peripheral gate 210a, an end portion morphology of the peripheral sub-gate 210 can be optimized without increasing mask costs, to avoid a rounding (rounding) problem caused by a single etching step, thereby greatly reducing a spacing between end portions of opposite peripheral sub-gates 210, and further significantly improving the degree of integration of peripheral components in the peripheral region PR.

Referring to FIG. 10A, FIG. 10B, and FIG. 10C, FIG. 10B is a schematic cross-sectional view of a semiconductor structure cut along cross-sections A-A' and B-B' in the schematic top view shown in FIG. 10A, and FIG. 10C is a schematic cross-sectional view of a semiconductor structure cut along a cross-section C-C' in the schematic top view shown in FIG. 10A. Bit line isolation structures 170 are filled in space in which a part of the initial bit line structures 140a, a part of the initial bit line contact layer 151a, and a part of the initial contact layer 160a are removed. Each of the bit line isolation structures 170 includes a first isolation portion 171 located between the bit line structures 140 and a second isolation portion 172 located between the bit line contact pads 150. A first width w1 of the first isolation portion 171 in the second direction D2 is greater than a second width w2 of the second isolation portion 172 in the second direction D2. The size and the position of the bit line isolation structure 170 correspond to the size and the position of the first opening K1 in the etching mask M2, the first isolation portion 171 is filled in space corresponding to the first rectangular opening of the first opening K1, and the second isolation portion 172 is filled in space corresponding to the second rectangular opening of the first opening K1. The first isolation portion 171 is configured to isolate adjacent bit line structures 140 in the dummy region DR, and the first isolation portion 171 is in contact with the bit line protective layer 140p on the sidewall of the bit line structure 140. The second isolation portion 172 is configured to isolate adjacent bit line contact pads 150 in the boundary region BR and is in contact with the sidewall of the bit line contact pad 150.

In some embodiments, a gate isolation structure 230 is filled in space in which a part of the peripheral gate 210a and a part of the peripheral isolation layer 220 are removed. The size and the position of the gate isolation structure 230 correspond to the size and the position of the second opening K2 in the etching mask M2. The gate isolation structure 230 is configured to isolate opposite end portions of the two opposite peripheral sub-gates 210 in the peripheral region PR. The gate isolation structure 230 is located between opposite first sidewalls s1 of the two opposite peripheral sub-gates 210, the gate isolation structure 230 and the bit line isolation structure 170 are formed synchronously and have the same material, and the first sidewalls s1 are sidewalls of the two opposite peripheral sub-gates 210 facing each other. The peripheral gate protective layer 210p is located on second sidewalls s2 of the two opposite peripheral sub-gates 210, and the second sidewall s2 is adjacent to the first sidewall s1. Alternatively, the peripheral gate protective layer 210p may be located on sidewalls of the two opposite peripheral sub-gates 210 facing away from each other, and the material of the peripheral gate protective layer 210p is different from that of the gate isolation structure 230. In an example, the peripheral gate protective layer 210p may be in a multi-layer structure, such as a multi-layer structure formed by NON, and is configured to protect a sidewall morphology of the peripheral sub-gate 210. The gate isolation structure 230 is in a single-layer structure, e.g., a single-layer structure formed by a low dielectric constant material such as silicon oxide, silicon nitride, silicon carbide, silicon carbide nitride, or silicon oxynitride, and is configured to reduce mutual interference and parasitic capacitance between the opposite peripheral sub-gates 210.

Referring to FIG. 11A, FIG. 11B, and FIG. 11C, FIG. 11B is a schematic cross-sectional view of a semiconductor structure cut along cross-sections A-A' and B-B' in the schematic top view shown in FIG. 11A, and FIG. 11C is a schematic cross-sectional view of a semiconductor structure cut along a cross-section C-C' in the schematic top view shown in FIG. 11A. The forming method for a semiconductor structure further includes the following: The initial contact layer 160a is patterned to form node contact layers arranged at intervals in the first direction D1, where a node spacing groove 180T exists between adjacent ones of the node contact layers; and a node isolation structure 180 is filled in the node spacing groove 180T. A part of the node contact layers is removed to form node contact structures 160. A plug groove 311T and a plug groove 312T are formed in the boundary region BR and the peripheral region PR. The following are formed: contact pad structures 190 located above the node contact structures 160, a bit line pad contact structure 311 located in the plug groove 311T in the boundary region BR, and a peripheral contact structure 312 located in the plug groove 312T in the peripheral region PR.

In some embodiments, the node contact structures 160 are arranged in an array in the first direction D1 and the second direction D2 and are in a quadrangle layout. To be specific, the node contact structures 160 arranged in the first direction D1 are substantially aligned in the first direction D1, and the node contact structures 160 arranged in the second direction D2 are substantially aligned in the second direction D2. The contact pad structures 190 are arranged in an array in the first direction D1 and the second direction D2 and are in a hexagonal layout. To be specific, each contact pad structure 190 has a substantially consistent distance from five adjacent contact pad structures 190 thereof, and the five adjacent contact pad structures 190 form a regular hexagon. The contact pad structures 190 are configured to connect to subsequently formed memory structures and are configured to implement most dense stacking of the memory structures. The material of the contact pad structure 190 includes a conductive material such as metal (e.g., tungsten (W), titanium (Ti), tantalum (Ta), ruthenium (Ru), cobalt (Co), and molybdenum (Mo)), a conductive metal nitride (e.g., titanium nitride and tantalum nitride), and a metal semiconductor compound (e.g., tungsten silicide, cobalt silicide, and titanium silicide).

In some embodiments, the plug groove 311T and the plug groove 312T are respectively formed synchronously in the boundary region BR and the peripheral region PR by employing an etching process. The plug groove 311T located in the boundary region BR may expose a part of the surface of the bit line contact pad 150, and the plug groove 312T located in the peripheral region PR may expose a part of the surface of the peripheral active region 113. The projection of the plug groove 311T, on the substrate, located in the boundary region BR is located at a center position of the projection of the bit line contact pad 150 on the substrate. The projection of the plug groove 312T, on the substrate, located in the peripheral region PR is located at a center position and two end positions of the projection of the peripheral active region 113 on the substrate.

In another example, the plug groove 311T may be formed in the boundary region BR and the plug groove 312T may be formed in the peripheral region PR by employing different steps. For example, after the plug groove 312T is first formed in the peripheral region PR, a sacrificial layer is filled in the plug groove 312T in the peripheral region PR, and then the plug groove 311T is formed in the boundary region BR, and the sacrificial layer filled in the plug groove 312T in the peripheral region PR is removed.

In some examples, after the part of the node contact layers is removed to form the node contact structures 160 and the plug groove 311T and the plug groove 312T are respectively formed in the boundary region BR and the peripheral region PR, the contact pad structures 190, the bit line pad contact structure 311, and the peripheral contact structure 312 may be formed synchronously by employing one-step deposition, thereby improving manufacturing process efficiency and reducing manufacturing costs.

Referring to FIG. 5A, FIG. 6A, FIG. 7A, FIG. 8A, and FIG. 12, the multiple initial bit line structures 140a include first initial bit line structures BL1a and second initial bit line structures BL2a arranged alternately in the second direction D2. The dummy region DR includes a first dummy region DR1 and a second dummy region DR2 respectively located on two sides of the array region AR in the first direction D1. Referring to FIG. 8A and FIG. 12, the first openings K1 expose a part of the first initial bit line structures BL1a located in the first dummy region DR1, and the first openings K1 further expose a part of the second initial bit line structures BL2a located in the second dummy region DR2. Referring to FIG. 9A and FIG. 12, the multiple bit line structures 140 are obtained after patterning processing is performed on the multiple initial bit line structures 140a based on the etching mask M2. The multiple bit line structures 140 extend in the first direction D1 and are arranged at intervals in the second direction D2. The multiple bit line structures 140 include first bit lines BL1 and second bit lines BL2 arranged alternately in the second direction D2. The first bit lines BL1 are formed by a part of the first initial bit line structures BL1a located in the array region AR and the second dummy region DR2, and the second bit lines BL2 are formed by a part of the second initial bit line structures BL2a located in the array region AR and the first dummy region DR1. The first bit lines BL1 and the second bit lines BL2 separately extend alternately to the second dummy region DR2 or the first dummy region DR1, so that the layout density of the bit line structures 140 in the dummy region DR can be reduced.

In some embodiments, referring to FIG. 12, the boundary region BR includes a first boundary region BR1 adjacent to the first dummy region DR1 and a second boundary region BR2 adjacent to the second dummy region DR2. The first boundary region BR1 and the second boundary region BR2 are respectively located on two sides of the memory region MR in the first direction D1. The first bit lines BL1 extend to the second dummy region DR2 and are connected to the bit line contact pads 150 located in the second boundary region BR2 in a one-to-one correspondence. The second bit lines BL2 extend to the first dummy region DR1 and are connected to the bit line contact pads 150 located in the first boundary region BR1 in a one-to-one correspondence. The peripheral region PR may include a first peripheral region PR1 adjacent to the first boundary region BR1 and a second peripheral region PR2 adjacent to the second boundary region BR2. The bit line isolation structure 170 located in the first boundary region BR1 and the first dummy region DR1 is sandwiched between adjacent second bit lines BL2. The bit line isolation structure 170 located in the second boundary region BR2 and the second dummy region DR2 is sandwiched between adjacent first bit lines BL1.

In the embodiments of the present disclosure, the bit line structures and the bit line contact pads are obtained by employing an etching mask patterning process, to form the bit line isolation structures located in the dummy region and the boundary region. In addition, each of the bit line isolation structures has the first isolation portion located between the bit line structures and the second isolation portion located between the bit line contact pads, and the first width of the first isolation portion is greater than the second width of the second isolation portion. This increases an effective area of the bit line contact pad, so that alignment between the bit line contact pad and the bit line pad contact structure can be increased, and a short circuit of a line between the bit line pad contact structure and a non-corresponding structure in the dummy region caused by an alignment deviation can be avoided, thereby improving the reliability of the semiconductor structure.

Based on the forming method for the semiconductor structure, an embodiment of the present disclosure further provides a semiconductor structure. FIG. 11A, FIG. 11B, and FIG. 11C are schematic diagrams of a semiconductor structure according to an embodiment of the present disclosure.

Referring to FIG. 11A, FIG. 11B, and FIG. 11C, the semiconductor structure includes the following: a substrate 110, where the substrate 110 includes a memory region MR and a boundary region BR sequentially adjacent to each other, and the memory region MR includes an array region AR and a dummy region DR; multiple bit line structures 140 located in the memory region MR, where the multiple bit line structures 140 extend in a first direction D1 and are arranged at intervals in a second direction D2, and the multiple bit line structures 140 include first bit lines BL1 and second bit lines BL2 arranged alternately in the second direction D2; multiple bit line contact pads 150 located in the boundary region BR, where the multiple bit line contact pads 150 are arranged at intervals in the second direction D2, and the second bit lines BL2 extend to the dummy region DR and are connected to the bit line contact pads 150 in a one-to-one correspondence; and bit line isolation structures 170 located in the dummy region DR and the boundary region BR, where each of the bit line isolation structures 170 includes a first isolation portion 171 located between the second bit lines BL2 and a second isolation portion 172 located between the bit line contact pads 150, and a first width w1 of the first isolation portion 171 is greater than a second width w2 of the second isolation portion 172. The first isolation portion 171 is located between a part of the second bit line BL2 in the dummy region DR, the first isolation portion 171 is in contact with a sidewall of the second bit line BL2 perpendicular to the second direction D2, and the first isolation portion 171 is further in contact with an end surface of the second bit line BL2 perpendicular to the first direction D1.

In some embodiments, the ratio of the width of the bit line contact pad 150 in the second direction D2 to the width of a bit line of the bit line structure 140 ranges from 3 to 5. In other words, the width of the bit line contact pad 150 is at least three times the width of the bit line, to increase an effective contact area of the bit line contact pad 150.

In some embodiments, the first width w1 of the first isolation portion 171 is basically equal to a spacing between adjacent ones of the second bit lines BL2. Alternatively, the first width w1 of the first isolation portion 171 is equal to a spacing between linear structures formed by adjacent ones of the first bit lines BL1 and bit line protective layers 140p at two sides.

In some embodiments, the second width w2 of the second isolation portion 172 is basically equal to the width of a bit line of the bit line structure 140. Alternatively, the second width w2 of the second isolation portion 172 is substantially equal to the width of a linear structure formed by the bit line structure 140 and bit line protective layers 140p at two side. For example, the ratio of the second width w2 to the width of one initial bit line structure 140a ranges from 0.8 to 1.5.

The substrate 110 further includes a peripheral region PR adjacent to the boundary region BR. Array active regions 111 and a shallow trench isolation structure 112 separating the array active regions 111 are provided in the memory region MR of the substrate 110. The array active regions 111 are arranged in an array in the first direction D1 and the second direction D2, and each array active region 111 extends in a third direction D3. Embedded word lines 120 are further formed in the substrate 110, the embedded word lines 120 are formed in the memory region MR, the embedded word lines 120 extend in the second direction D2 and are arranged at intervals in the first direction D1, and intersect the array active regions 111, and each array active region 111 intersects two embedded word lines 120.

In some embodiments, referring to FIG. 12, the dummy region DR includes a first dummy region DR1 and a second dummy region DR2 respectively located on two sides of the array region AR in the first direction, and the boundary region BR includes a first boundary region BR1 and a second boundary region BR2 respectively located on two sides of the memory region MR in the first direction D1. The first bit lines BL1 extend to the second dummy region DR2 and are connected to the bit line contact pads 150 located in the second boundary region BR2 in a one-to-one correspondence. The second bit lines BL2 extend to the first dummy region DR1 and are connected to the bit line contact pads 150 located in the first boundary region BR1 in a one-to-one correspondence.

In some embodiments, referring to FIG. 12, the substrate 110 further includes a peripheral region PR, and the semiconductor structure further includes the following: two opposite peripheral sub-gates 210 located in the peripheral region PR; a gate isolation structure 230 located between opposite first sidewalls s1 of the two opposite peripheral sub-gates 210, where the gate isolation structure 230 has the same material as the bit line isolation structures 170; and a peripheral gate protective layer 210p located on second sidewalls s2 of the two opposite peripheral sub-gates 210, where the second sidewalls s2 are adjacent to the first sidewalls s1, and the material of the peripheral gate protective layer 210p is different from the material of the gate isolation structure 230.

In some embodiments, as shown in FIG. 11B and FIG. 11C, the semiconductor structure further includes multiple node contact structures 160 located in the array region AR, and the multiple node contact structures 160 are arranged in an array in the first direction D1 and the second direction D2. Contact pad structures 190 are further formed above the node contact structures 160, and the contact pad structures 190 are configured to connect to a memory structure, e.g., a capacitor.

In some embodiments, as shown in FIG. 11B and FIG. 11C, the node contact structures 160 located in the array region AR are embedded in the substrate 110 and in contact with the array active regions 111 in the substrate 110. The second isolation portion 172 located in the dummy region DR is located on the substrate 110, and the bottom surface of the second isolation portion 172 is flush with the top surface of the substrate 110.

In some embodiments, the substrate 110 further includes a substrate protective layer located on the top surfaces of the array active regions 111 and the shallow trench isolation structure 112. The second isolation portion 172 located in the dummy region DR may be in contact with the substrate protective layer and isolated from the array active region 111. The top surface of the array active region 111 of the substrate 110 in the dummy region DR is flat. The top surface of the array active region 111 of the substrate 110 in the array region AR is formed with a recess R, and the recess R is configured to accommodate the node contact structure 160.

In some embodiments, the semiconductor structure includes a memory. The memory may be a dynamic random access memory. Alternatively, the memory may be a memory known in the art, e.g., a phase change memory or a ferroelectric memory.

Various semiconductor structures shown in the specific implementations may be employed in electronic devices with a storage function. Each of the electronic devices may be a terminal device, e.g., a mobile phone, a tablet computer, or a smart wristband, or may be a personal computer (personal computer, PC), a server, or a workstation. The storage function in the electronic devices may be implemented by the following memory: a dynamic random access memory (DRAM), a ferroelectric random access memory (FRAM), a phase change memory (PCM), a magnetic random access memory (MRAM), or a resistive random access memory (RRAM).

The foregoing descriptions are merely specific implementations of the present disclosure, but are not intended to limit the protection scope of the present disclosure. Any variation or replacement readily figured out by a person skilled in the art within the technical scope disclosed in the present disclosure shall fall within the protection scope of the present disclosure. Therefore, the protection scope of the present disclosure shall be subject to the protection scope of the claims.

What is claimed is:

1. A forming method for a semiconductor structure, comprising:
providing a substrate, the substrate comprising a memory region and a boundary region sequentially adjacent to each other, and the memory region comprising an array region and a dummy region;
forming an initial conductive layer on the substrate;
patterning the initial conductive layer in the memory region to form a plurality of initial bit line structures, and retaining the initial conductive layer in the boundary region to form an initial bit line contact layer, the plurality of initial bit line structures extending in a first direction and being arranged at intervals in a second direction;
forming an etching mask provided with a plurality of first openings, the plurality of first openings exposing a part of the initial bit line structures in the dummy region and a part of the initial bit line contact layer in the boundary region;
patterning the initial bit line structures and the initial bit line contact layer by employing the etching mask to form a plurality of bit line structures and a plurality of bit line contact pads; and
forming bit line isolation structures, each of the bit line isolation structures comprising a first isolation portion located between the bit line structures and a second isolation portion located between the bit line contact pads, and a first width of the first isolation portion being greater than a second width of the second isolation portion.

2. The forming method for a semiconductor structure according to claim 1, wherein the substrate further comprises a peripheral region and at the time of patterning the initial conductive layer in the memory region to form a plurality of initial bit line structures, the method further comprises: patterning the initial conductive layer in the peripheral region to form peripheral gates; and
after the patterning the initial conductive layer in the memory region to form a plurality of initial bit line structures, the method further comprises:
forming a peripheral gate protective layer on a sidewall of each of the peripheral gates, and forming a bit line protective layer on a sidewall of each of the initial bit line structures.

3. The forming method for a semiconductor structure according to claim 2, wherein the etching mask is further provided with a second opening, the second opening exposes a part of the peripheral gates in the peripheral region, and at the time of patterning the initial bit line structures and the initial bit line contact layer by employing the etching mask, the method further comprises:
patterning each of the peripheral gates by employing the etching mask to form two opposite peripheral sub-gates, wherein an arrangement direction of the two opposite peripheral sub-gates is an extension direction of the peripheral gates.

4. The forming method for a semiconductor structure according to claim 2, after the patterning the initial conductive layer in the memory region to form a plurality of initial bit line structures, further comprising:
forming a peripheral mask, wherein the peripheral mask covers the dummy region, the boundary region, and the peripheral region;
removing, by employing the peripheral mask, the bit line protective layer located on the substrate in the array region to expose the substrate in the array region; and
removing the peripheral mask and filling an initial contact layer between the plurality of initial bit line structures.

5. The forming method for a semiconductor structure according to claim 4, further comprising: patterning the initial contact layer to form node contact layers arranged at intervals in the first direction, wherein a node spacing groove exists between adjacent ones of the node contact layers; and filling the node spacing groove with a node isolation structure.

6. The forming method for a semiconductor structure according to claim 5, further comprising:
removing a part of the node contact layers to form node contact structures;
forming plug grooves in the boundary region and the peripheral region; and
forming contact pad structures located above the node contact structures, a bit line pad contact structure located in the plug groove in the boundary region, and a peripheral contact structure located in the plug groove in the peripheral region.

7. The forming method for a semiconductor structure according to claim 1, wherein the plurality of initial bit line structures comprise first initial bit line structures and second initial bit line structures arranged alternately in the second direction; and the dummy region comprises a first dummy region and a second dummy region respectively located on two sides of the array region in the first direction;
the first openings expose a part of the first initial bit line structures located in the first dummy region, and the first openings further expose a part of the second initial bit line structures located in the second dummy region; and
the plurality of bit line structures extend in the first direction and are arranged at intervals in the second direction, the plurality of bit line structures comprise first bit lines and second bit lines arranged alternately in the second direction, the first bit lines are formed by a part of the first initial bit line structures located in the array region and the second dummy region, and the second bit lines are formed by a part of the second initial bit line structures located in the array region and the first dummy region.

8. A semiconductor structure, comprising:
a substrate, the substrate comprising a memory region and a boundary region sequentially adjacent to each other, and the memory region comprising an array region and a dummy region;
a plurality of bit line structures located in the memory region, the plurality of bit line structures extending in a first direction and being arranged at intervals in a second direction, and the plurality of bit line structures comprising first bit lines and second bit lines arranged alternately in the second direction;
a plurality of bit line contact pads located in the boundary region, the plurality of bit line contact pads being arranged at intervals in the second direction, and the second bit lines extending to the dummy region and being connected to the bit line contact pads in a one-to-one correspondence; and
bit line isolation structures located in the dummy region and the boundary region, each of the bit line isolation structures comprising a first isolation portion located between the second bit lines and a second isolation portion located between the bit line contact pads, and a first width of the first isolation portion being greater than a second width of the second isolation portion.

9. The semiconductor structure according to claim 8, wherein the dummy region comprises a first dummy region and a second dummy region respectively located on two sides of the array region in the first direction, and the boundary region comprises a first boundary region and a second boundary region respectively located on two sides of the memory region in the first direction;
the first bit lines extend to the second dummy region and are connected to the bit line contact pads located in the second boundary region in a one-to-one correspondence; and
the second bit lines extend to the first dummy region and are connected to the bit line contact pads located in the first boundary region in a one-to-one correspondence.

10. The semiconductor structure according to claim 8, wherein the substrate further comprises a peripheral region and the semiconductor structure further comprises:
two opposite peripheral sub-gates located in the peripheral region;
a gate isolation structure located between opposite first sidewalls of the two opposite peripheral sub-gates, wherein the gate isolation structure has a same material as the bit line isolation structures; and
a peripheral gate protective layer located on second sidewalls of the two opposite peripheral sub-gates, wherein the second sidewalls are adjacent to the first sidewalls, and a material of the peripheral gate protective layer is different from the material of the gate isolation structure.

11. The semiconductor structure according to claim 8, wherein the first width of the first isolation portion is equal to a spacing between adjacent ones of the second bit lines.

12. The semiconductor structure according to claim 8, wherein the second width of the second isolation portion is equal to a width of a bit line of each of the bit line structures.

13. The semiconductor structure according to claim 8, further comprising:
a plurality of node contact structures located in the array region, wherein the plurality of node contact structures are arranged in an array in the first direction and the second direction.

14. The semiconductor structure according to claim 13, wherein the node contact structures located in the array region are embedded in the substrate and in contact with array active regions in the substrate; and
the second isolation portion located in the dummy region is located on the substrate and is flush with a top surface of the substrate.
